(19) United States
(12) Patent Application Publication
(10) Pub. No.: US 2020/0081778 A1
(43) Pub. Date: Mar. 12, 2020

(54) DISTRIBUTED STORAGE SYSTEM, METHOD AND APPARATUS

(71) Applicant: Goke US Research Laboratory, Santa Clara, CA (US)

(72) Inventor: Chandra Varanasi, Santa Clara, CA (US)

(21) Appl. No.: 16/128,431

(22) Filed: Sep. 11, 2018

(51) Int. Cl. G06F 11/10; H03M 13/29

(52) U.S. Cl. CPC G06F 11/1076; H03M 13/2942

(57) ABSTRACT

A system, method and apparatus for encoding and decoding data in a distributed data storage and retrieval system. Data destined for storage is converted into information vectors, and the information vectors are multiplied by a binary encoder matrix to form systematic codewords. The binary encoder matrix is formed as a binary representation of an encoding matrix, the encoding matrix matrix comprising an identity matrix and a special Cauchy matrix, where each element in encoding matrix is an element of an extension field.

### BACKGROUND

### I. Field of Use

The present invention relates to the field of digital data storage and more specifically to an encoding scheme for distributed encoding and storage systems, such as RAID storage systems.

### II. Description of the Related Art

Commercial mass data storage has become a vital part of the modern economy. Thousands of companies rely on secure, fault-proof data storage to serve their customers.

Data storage in commercial settings typically provides for some form of data protection to guard against accidental data loss due to component and device failures, and man-made or natural disasters. The simplest form of protection is known as redundancy. Redundancy involves making multiple copies of the same data, and then storing the copies on a separate, physical drives. If a failure occurs on one drive, the data may be recovered simply by accessing it on another drive. This is obviously costly in terms of physical storage requirements.

More advanced recovery systems use a redundant array of independent disks (RAID). RAID systems typically utilize erasure encoding to mitigate accidental loss of data. Erasure encoding breaks blocks of data into n multiple, equal-sized symbols and adds m parity symbols. Thus, a RAID system stores n+m symbols and is resilient against failures in up to any m symbol failures.

In such RAID storage systems, given k information disks or storage devices, a straightforward RAID encoding involves generating one parity disk—a (k+1)th disk—as an XOR of the bits in identical positions in the k storage devices. If any one of the k disks fails, it can be reconstructed by XOR-ing the contents of the remaining (k−1) disks and the parity disk. The code is maximum-distance separable (MDS) in the sense that the number of disks that can be reconstructed equals the number of parity disks which, in this case, is one. The well-known Reed Solomon (RS) code preserves the MDS property, that is, it allows reconstruction of as many disks as the number of parity disks used, but does not rely solely on XOR operations for data reconstruction.

Erasure encoding techniques such as Reed-Solomon codes requires substantial computational resources, because it relies on arithmetic on symbols from a finite field of size 2^{m} (where m is a number of bits in each symbol), also called an extension field GF(2^{m}), instead of arithmetic on bits{0,1} or a base field GF(2), from which the extension field is formed. The advantage of arithmetic based on a GF(2) field is that the arithmetic operations can be performed using simple XOR gates.

It would be desirable to encode data using an encoding technique that adheres to the three, desirable properties described above, i.e., the code is MDS, it is able to correct for multiple disk failures in a storage system, and it avoids the use of complex arithmetic.

### SUMMARY

The embodiments described herein relate to an apparatus, system and method for data encoding, storage, retrieval and decoding. In one embodiment, a distributed data encoding and storage method is described that provides for XOR-only decoding, comprising generating an information vector from received data, the information vector comprising information symbols, generating a codeword from the information vector, the codeword comprising information symbols and parity symbols, and distributing the information symbols and the parity symbols to a plurality of storage mediums, respectively, wherein the parity symbols are formed by multiplying the information vector by a portion of a binary encoder matrix, the binary encoder matrix comprising a binary representation of an encoding matrix in extension field form.

In another embodiment, a method for data recovery in a distributed data storage system is described, comprising retrieving a plurality of information symbols and a plurality of parity symbols from a plurality of storage mediums, the plurality of information symbols and plurality of parity symbols comprising a codeword formed from a binary information vector and a binary encoder matrix, wherein the binary encoder matrix comprises a binary representation of an identity matrix concatenated with a Cauchy matrix, determining that at least one of the information symbols failed, identifying a sub-matrix within the Cauchy matrix, the sub-matrix identified in accordance with an identity of the failed information symbols, computing an inverse matrix from the sub-matrix, generating a column vector from codeword symbols that did not fail, and multiplying the inverse matrix by the column vector.

### BRIEF DESCRIPTION OF THE DRAWINGS

The features, advantages, and objects of the present invention will become more apparent from the detailed description as set forth below, when taken in conjunction with the drawings in which like referenced characters identify correspondingly throughout, and wherein:

FIG. 1 is a simplified block diagram of one embodiment of a data storage and retrieval system used for encoding, storing, retrieving, and decoding data in accordance with the teachings herein;

FIG. 2 is a functional block diagram of one embodiment of a data storage server as shown in FIG. 1;

FIG. 3 is an encoding matrix used as a basis to encode data;

FIGS. 4A and 4B are a flow diagram illustrating one embodiment of a method performed by the data storage server as shown in FIG. 2 to encode, store, retrieve and decode data;

FIG. 5 is a table of 4-bit vectors as powers of a primitive α in an extension field GF(2⁴) formed from a primitive polynomial 1+x+x⁴;

FIG. 6 is a table of pre-computed additions of the field elements as shown in FIG. 5;

FIGS. 7A and 7B represent a binary encoder matrix formed from the encoding matrix as shown in FIG. 3;

FIG. 8 is a flow diagram of another embodiment of a method performed by the data storage server as shown in FIG. 2 to encode, store, retrieve and decode data; and

FIG. 9 illustrates a first binary vector and a second binary vector for use in an alternative coding and decoding embodiment, each binary vector generated from a binary information vector V_{bin}.

### DETAILED DESCRIPTION

Certain aspects and embodiments of this disclosure are provided below. Some of these aspects and embodiments may be applied independently and some of them may be applied in combination as would be apparent to those of skill in the art. In the following description, for the purposes of explanation, specific details are set forth in order to provide a thorough understanding of embodiments of the invention. However, it will be apparent that various embodiments may be practiced without these specific details. The figures and description are not intended to be restrictive.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing the spirit and scope of the invention as set forth in the appended claims.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The terms “computer-readable medium” “memory” and “storage medium” includes, but is not limited to, portable or non-portable storage devices, optical storage devices, and various other mediums capable of storing, containing, or carrying instructions) and/or data. These terms each may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, RAM, ROM, flash memory, disk drives, etc. A computer-readable medium or the like may have stored thereon code and/or machine-executable instructions that may represent a procedure, a function, a subprogram, a program, a routine, a subroutine, a module, a software package, a class, or any combination of instructions, data structures, or program statements. A code symbol may be coupled to another code symbol or a hardware circuit by passing and/or receiving information, data, arguments, parameters, or memory contents. Information, arguments, parameters, data, etc. may be passed, forwarded, or transmitted via any suitable means including memory sharing, message, passing, token passing, network transmission, or the like.

Furthermore, embodiments may be implemented by hardware, software, firmware, middleware, microcode, hardware description languages, or any combination thereof. When implemented in software, firmware, middleware or microcode, the program code, i.e., “processor-executable code”, or code symbols to perform the necessary tasks (e.g., a computer-program product) may be stored in a computer-readable or machine-readable medium. A processor(s) may perform the necessary tasks.

The embodiments described herein provide specific improvements to a data storage and retrieval system. For example, the embodiments allow the storage and retrieval system to recover data stored in one or more storage mediums in the event of erasures, or errors, due to, for example, media failures or noise, using only XOR arithmetic. Using XOR arithmetic avoids the use of complex arithmetic, such as polynomial calculations rooted in Galois field theory, as is the case with traditional error decoding techniques such as Reed-Solomon. Limiting the calculations to only XOR arithmetic improves the functionality of a data storage and retrieval system, because it allows the use of cheaper, less-powerful processors, and results in faster storage and retrieval than techniques known in the art.

Given k storage mediums, referred to herein as “disk drives” or simply “disks”, prior art RAID encoding involves generating a parity data symbol from an XOR of respective codeword symbols stored in identical positions in the k storage devices, and storing the parity data symbol on a (k+1)th disk (a parity disk). If any one of the k disks fail, data stored in that disk can be reconstructed by XOR-ing the contents of the disks that did not fail and the parity disk. This simple, XOR coding technique is maximum distance separable (MDS) in the sense that the number of disks that can be reconstructed equals the number of parity disks, which is one. However, increasing the correction capabilities of such a prior art RAID storage system to more than one disk, while preserving the MDS property, requires complex computations that slow access times. For example, the well-known Reed Solomon (RS) code preserves the MDS property—that is, it allows reconstruction of as many disks as the number of parity disks that are used—but does not rely solely on XOR operations for reconstruction. By treating each sequence of ‘m’ bits—for a chosen integer m—as one of the possible 2^{m} symbols, the Reed-Solomon decoding algorithm relies on calculations on symbols from a finite field of size 2^{m}, also called an extension field GF(2^{m}), instead of simple arithmetic using values of “1” and “0” in a base field GF(2), from which the extension field is formed. This complex coding scheme requires expensive, computationally-intense processing while also increasing the time needed to both encode and decode data.

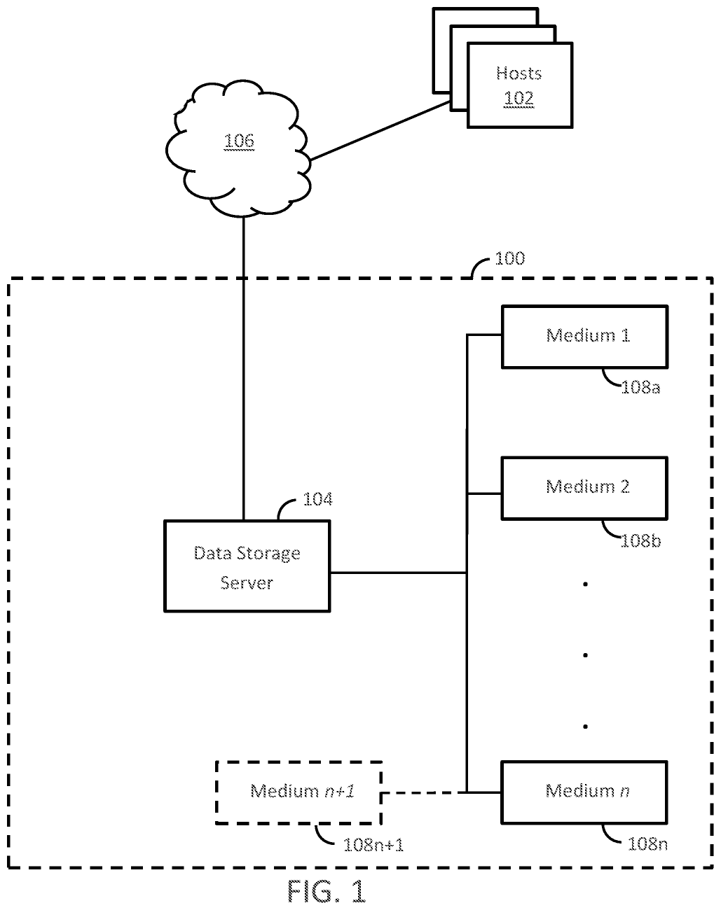

FIG. 1 illustrates a functional block diagram of one embodiment of a distributed storage and retrieval system 100 in accordance with the teachings herein. In the embodiment shown in FIG. 1, numerous hosts 102 provide data to data storage server 104 via wide-area network 106, such as the Internet, and data storage and retrieval server 104 processes the data for storage in a plurality of data storage medium 108a-108n. Also shown is storage medium 108n+1, used in an alternative embodiment, described later herein. Such data storage systems are used in cloud storage models, in which digital data may be stored in logical pools, the storage mediums may span multiple servers (and often locations), and the physical environment is typically owned and managed by a hosting company. These cloud storage providers are responsible for keeping the data available and accessible, and the physical environment protected and running. People and organizations buy or lease storage capacity from the providers to store user, organization, or application data. Example of such cloud storage include Amazon's S3, Google's Cloud Storage and Microsoft's Azure storage platforms.

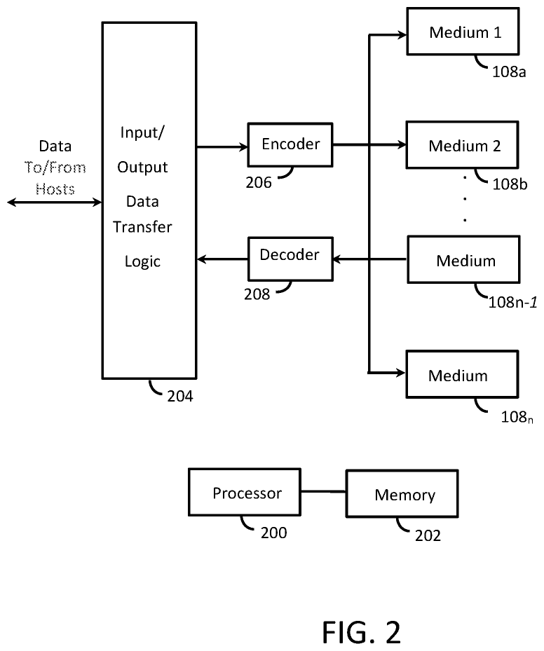

FIG. 2 is a functional block diagram of one embodiment of data storage and retrieval server 104. Digital data is received from hosts 102 by input/output data transfer logic 204, where it is parsed into “blocks” of a predetermined number of symbols, such as 128 symbols. Input/output data transfer logic 204 comprises circuitry well-known in the art for receiving encoded and/or unencoded data from a large number of hosts 102, such as cellular telephones, personal computers, cloud-based servers, etc., for forming the blocks from the data, and for providing the blocks to encoder 206.

Encoder 206 receives the blocks from input/output data transfer logic 204 and encodes each block using a special coding technique that preserves an MDS property, allows for data recovery in the event of multiple disk failures, and does not rely on complex mathematical equations, such as polynomials in an extension field, as prior-art coding techniques do. As such, encoding (and decoding) may be performed by simple logic gates, and decoding may be performed without having to use complex mathematical equations.

Encoding each block yields a codeword, comprising equal-sized information symbols and parity symbols. The symbols are then distributed (i.e., stored) across an equal number of storage mediums 108. In one embodiment, the codeword is systematic, meaning that the information symbols of the codeword are identical to the block from which it is formed, and the parity symbols are separate and appended to the information symbols. In this embodiment, each data symbol and parity symbol is stored, respectively, in a respective storage medium 108.

For example, a systematic MDS codeword of length n=(q−1) may be defined, where q=2^{m}, and m is equal to a number of bits per symbol. In coding terminology, a systemic codeword of length n comprises k information bits followed by (n−k) parity bits. So, if m is chosen, for example, equal to 4, each codeword will have a length of n=15 symbols. If k is chosen as 12 information symbols, the number of parity symbols is (n−k)=15−12=3, and the number of storage mediums is equal to n, in this case 15. Using this example, a decoder can then recover up to 3 failed information symbols in each retrieved codeword from the plurality of storage mediums 108. In another example, in order to recover 4 failed information symbols, (n−k)=4, and thus n=11 information symbols in each codeword. In general, a decoder can correct up to as many failed information symbols as there are number of parity symbols in each codeword.

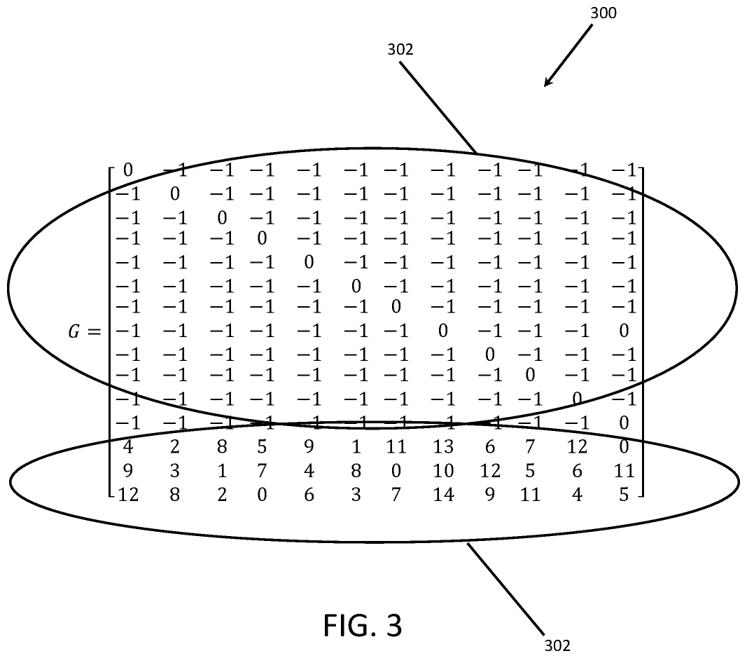

Encoding the blocks may comprise converting each symbol in a block into binary form, creating a binary information vector. Then, the binary information vector is multiplied by a binary encoder matrix formed from an encoding matrix, the encoding matrix comprising an identity matrix concatenated with a special Cauchy matrix. A Cauchy matrix is a matrix where every square sub-matrix is invertible, and where every square sub-matrix is itself a Cauchy matrix. The elements of both the identity matrix and the special Cauchy matrix comprise members of an extension field GF(2^{m}). Such an encoding matrix 300 is shown in FIG. 3, as encoding matrix G. Continuing with the example where each codeword is 15 symbols in length, with 12 information symbols and 3 parity symbols, and the number of bits per symbol is 4, encoding matrix G comprises identity matrix 302 comprising k rows and k columns, in this example, 12, concatenated with special Cauchy matrix 304, comprising (n−k) rows and k columns, or 3 rows by 12 columns.

In one embodiment, the binary encoder matrix is generated by processor 200 from the encoding matrix 300, and the binary encoder matrix is stored in memory 202. Alternatively, a separate computer generates the binary encoder matrix from the encoding matrix 300, and it is then provided to data storage server 104 for storage in memory 202. Generation of the elements in the encoding matrix and the binary encoder matrix is provided in greater detail later herein.

After one or more codewords have been generated and stored across storage mediums 108a-108n by encoder 206, at some time later, a request to retrieve data may be received by data storage and retrieval server 104 from one of the hosts 102. In response, for each codeword, decoder 208 retrieves codeword symbols and one or more parity symbols in parallel from the storage mediums 108a-108n. The data and parity symbols are assembled to form a retrieved codeword, and then the retrieved codeword is decoded by decoder 208 using XOR arithmetic, avoiding complex arithmetic related to the use of polynomial extension fields, as is the case with traditional error decoding techniques used in such error correction codes such as Reed-Solomon. Limiting the calculations to only XOR arithmetic improves the functionality of data storage server 104, because it allows the use of cheaper, less-powerful processors, and results in faster storage and retrieval than techniques known in the art. Data storage and retrieval server 104 can tolerate simultaneous storage medium failures, up to the number of parity symbols used in each codeword, in this example, 3 storage medium failures. The decoding process is described in greater detail later herein.

In general, each of the functional blocks shown in FIG. 2 may utilize either separate or shared processing and memory resources. While encoder 206 and decoder 208 are shown as separate functional blocks in FIG. 2, in practice, their functionality is often combined into a single, specialized ASIC, System on a Chip (SoC), microprocessor or microcontroller. In other embodiments, each of encoder 206 and 208 comprise a separate microprocessor, microcontrollers, ASICS or SoC's, and each may comprise electronic memory for storing information pertinent to the encoding and decoding process, respectively. In yet still other embodiments, some of the functionality to encode, store, retrieve and decode may be performed by processor 200, while other functionality may be performed by the various functional blocks shown in FIG. 2. In this embodiment, processor 200 executes processor-executable instructions stored in memory 202 to control both encoder 206 and decoder 208 during the encoding, storing, retrieving and decoding processes. Processor 400 may be selected based on processing capabilities, power-consumption properties, and/or cost and size considerations. Memory 202 comprises one or more information storage devices, such RAM, ROM, Flash, and/or virtually any other type of electronic memory device. Typically, memory 202 comprises more than one type of memory. For example, a ROM may be used to store static processor-executable instructions, while a RAM memory or flash memory may be used to store data related to the encoding and decoding processes. For example, memory 202 may be used to store the binary encoder matrix, as described below.

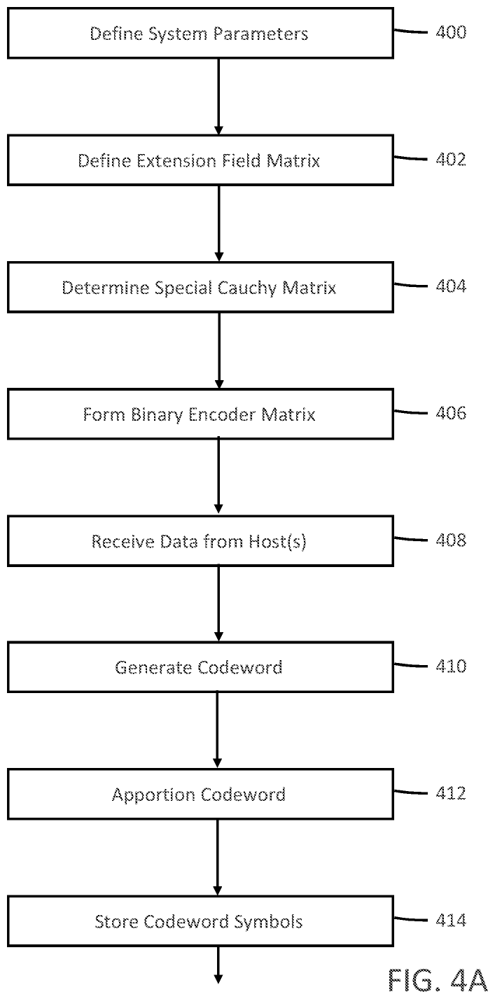

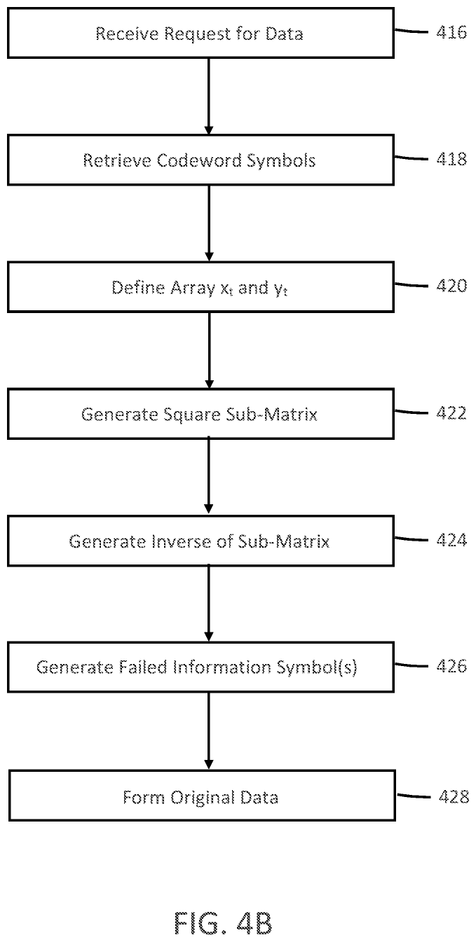

FIGS. 4A and 4B are a flow diagram illustrating one embodiment of a method performed by data storage server 104 to encode, store, retrieve and decode data received from one or more hosts 102. In this embodiment, the method is described as being performed by input/output data transfer logic 204, encoder 206, decoder 208 and processor 200, executing processor-executable instructions stored in memory 202 or in a memory associated with one of the aforementioned processing devices. It should be understood that the steps shown in FIGS. 4A and 4B could alternatively be performed by processor 200 controlling functions provided by input/output data transfer logic 204, encoder 206, and decoder 208. It should be further understood that in some embodiments, not all of the steps shown in FIGS. 4A and 4B are performed and that the order in which the steps are carried out may be different in other embodiments. It should be further understood that some minor method steps have been omitted for purposes of clarity.

At block 400, various coding parameters are defined, taking into account things such as a number of storage mediums 108 available to data storage and retrieval system 100, the cost of such storage mediums, a desired encoding/storage speed, a desired retrieval/decoding speed, processing capabilities of a given processor 200, encoder 206 and decoder 208, and other constraints. For the remainder of this discussion, the parameters used in the example above with respect to FIG. 2 will be used, i.e., 4 bits per symbol, a systematic MDS codeword of length 15. The number of symbols in each codeword is generally also equal to the number of storage mediums. If it is desired to be able to recover up to 3 simultaneous failures of storage mediums, each codeword is defined as having 12 information symbols 3 parity symbols.

At block 402, an encoding matrix is defined, for example, extension field G as shown in FIG. 3. The encoding matrix may be formed by processor 200 or by a computer separate from data storage and retrieval system 100. As discussed previously, the encoding matrix comprises an n by k sized matrix, in this example, 15 rows by 12 columns, comprising an identity matrix 302 concatenated with a special Cauchy matrix 304. The elements of both the identity matrix and the special Cauchy matrix comprise members of an extension field GF(2^{m}), as shown in FIG. 3. The identity matrix 302 comprises k rows and k columns, in this example, 12, while the special Cauchy matrix 304 comprises (n−k) rows and k columns, or 3 rows by 12 columns.

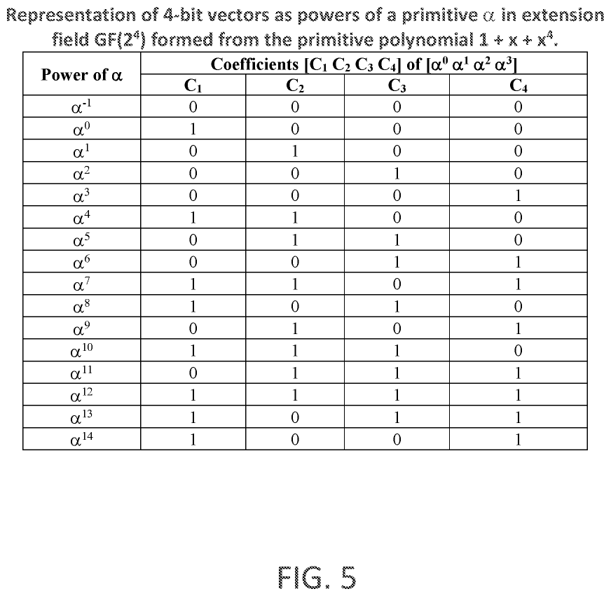

The identity matrix 302 comprises elements “0” and “4”, which are powers of a “primitive” α. Given an integer ‘m’ (i.e., the number of bits in each symbol), an extension field of size 2^{m}, denoted as GF(2^{m}), may be formed from a binary alphabet having elements {0,1} or the base field GF(2). The extension field consists of 2^{m} m-bit vectors, and each vector may be represented by a power of a primitive of a polynomial, denoted as α, ranging from −1 to (2^{m}−2), or from −1 to 14 in this example. A table of 4-bit vectors as powers of a primitive α in an extension field GF(2⁴) formed from a primitive polynomial 1+x+x⁴ are shown in FIG. 5. Using a polynomial of degree ‘m’, each m-bit vector in the extension field GF(2^{m}) is represented as coefficients of a unique power of a primitive in GF(2^{m}). A primitive in GF(2^{m}) is one of the members of GF(2^{m}) which also happens to be a root of the polynomial. Using the fact that α is a root of the primitive polynomial, it is relatively straightforward to generate the field elements as powers of α as shown in the left-hand column of the extension field in FIG. 5. An extension field for m=4 may be described using a particular primitive polynomial of degree 4, in one embodiment, f(x)=1+x+x⁴. This extension field defines all sixteen, 4-bit vectors of the extension field using a primitive α in the field. Since α is a root of the polynomial, 1+α+α⁴=0, or, α⁴=−(1+α). Since −1=1 in GF(2) arithmetic, α⁴=1+α. The relationship is used to describe each vector of the extension field GF(2⁴) as a unique power of α. For example, α⁵=α·α⁴=α(1+α)=α+α². If each 4-bit vector is interpreted as coefficients [C₁ C₂ C₃ C₄] of a m−1 degree polynomial, in this example, a 3^{rd} degree polynomial, of c₁+c₂α+c₃α²+c₄α³, then α+α² may be represented by [0 1 1 0]. α⁻¹ is used to denote an all-zero vector, shown in FIG. 5 as the first row of the extension field.

At block 404, the special Cauchy matrix 304 is determined, using the matrix addition, multiplication, division and inverse, as described below.

Addition of Field Elements:

The addition of two field elements is a bit-by-bit XOR addition of the corresponding vectors. As an example, the addition of the two field elements α⁵+α⁶ is a bit-by-bit XOR addition of the two corresponding vectors [0 1 1 0] and [0 0 1 1]=[0 1 0 1], which in turn, refers to α⁹. Thus, α⁵+α⁶=α⁹. Another way to do addition is to take the matrix representation of each field element and perform an XOR addition of the two matrices. The resulting matrix can be mapped back either to the power of α, or to its corresponding vector. Again as an example,

$${α}^{4} + {α}^{13} = [ \begin{matrix}1 & 0 & 0 & 1 \\ 1 & 1 & 0 & 1 \\ 0 & 1 & 1 & 0 \\ 0 & 0 & 1 & 1\end{matrix} ] ⊕ [ \begin{matrix}1 & 1 & 1 & 0 \\ 0 & 0 & 0 & 1 \\ 1 & 0 & 0 & 0 \\ 1 & 1 & 0 & 0\end{matrix} ] = [ \begin{matrix}0 & 1 & 1 & 1 \\ 1 & 1 & 0 & 0 \\ 1 & 1 & 1 & 0 \\ 1 & 1 & 1 & 1\end{matrix} ] = {α}^{11}$$

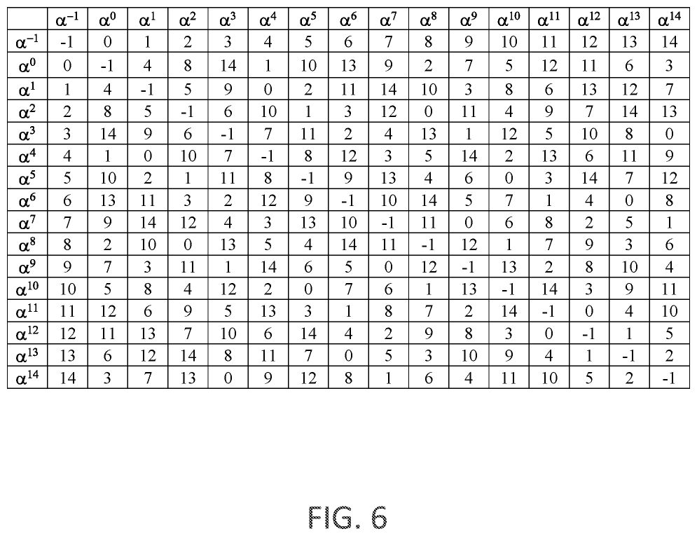

Given that the addition operation is straightforwardly defined as above, in one embodiment, a table of pre-computed field element additions may be stored, in one embodiment in memory 202, comprising a matrix or table of size 2^{m}×2^{m}, where the table elements are represent additions between every pair of field elements in FIG. 5. For m=4, based on FIG. 5 and the definition of addition above, such a pre-computed table is shown in FIG. 6.

Multiplication of Field Elements.

Unlike addition, multiplication is performed using the power of α representation itself. The powers themselves are simply added together, then added modulo (2^{m}−1). As an example, referring to FIG. 5, α¹¹·α¹³=α⁹, since 11+13=24, and 24 mod 15=9. In another embodiment, multiplication may be performed in the matrix domain by multiplying two matrices together, keeping in mind that whenever an addition needs to be done, it is an XOR addition. As an example,

$${α}^{4} \cdot {α}^{13} = [ \begin{matrix}1 & 0 & 0 & 1 \\ 1 & 1 & 0 & 1 \\ 0 & 1 & 1 & 0 \\ 0 & 0 & 1 & 1\end{matrix} ] ⊕ [ \begin{matrix}1 & 1 & 1 & 0 \\ 0 & 0 & 0 & 1 \\ 1 & 0 & 0 & 0 \\ 1 & 1 & 0 & 0\end{matrix} ] = [ \begin{matrix}0 & 0 & 1 & 0 \\ 0 & 0 & 1 & 1 \\ 1 & 0 & 0 & 1 \\ 0 & 1 & 0 & 0\end{matrix} ] = {α}^{2}$$

Thus, there are three possible representations of an extension field vector: (1) as a power of α (2) as a vector, and (3) as a matrix. Moreover, there are more than one way to perform addition and multiplication between field elements.

The products between pairs of field elements may be pre-computed to create a 2^{m}9×2^{m} matrix—or, table—and simply look up that table whenever multiplication between field elements is needed.

Inverse of a Field Element.

In an extension field, α^{p}=1 where p=2^{m}−1. This observation may be used to define an inverse of a non-zero field element αⁱ to be α^{j}, where j is such that α^{(i+j)}=1. With respect to FIG. 5, m=4, p=15. So, as examples, the inverse of α⁷=α⁸, and the inverse of α¹¹=α⁴. The inverse may be defined as 1/field element, i.e., the inverse of a⁷ is 1/a⁷. Since the 1 in the numerator can be replaced by α¹⁵, 1/α⁷=α¹⁵/α⁷=α⁸. The all-zero element in the extension field has no inverse defined. For a particular m, a table may be pre-computed, listing the inverses of all the non-zero field elements. For example, a table of precomputed inverses for the non-zero elements of FIG. 5 is shown below:

List of Inverses of non-zero Field Elements in GF(2⁴)

| | Field Element | | | | | | | | | | | | | | |
|---|---|---|---|---|---|---|---|---|---|---|---|---|---|---|---|
| | α⁰ | α¹ | α² | α³ | α⁴ | α⁵ | α⁶ | α⁷ | α⁸ | α⁹ | α¹⁰ | α¹¹ | α¹² | α¹³ | α¹⁴ |
| Inverse of Field Element | α⁰ | α¹⁴ | α¹³ | α¹² | α¹¹ | α¹⁰ | α⁹ | α⁸ | α⁷ | α⁶ | α⁵ | α⁴ | α³ | α² | α¹ |

Division of Field Elements.

Using the notion of inverse of a field element, division between two field elements may be defined as αⁱ/α^{j}=αⁱ. (1/α^{j}) to be the multiplication of αⁱ and the inverse of α^{j}.

The special Cauchy matrix 304 comprises (n−k) rows and k columns, in this case, 3 rows and 12 columns. In one embodiment, two, separate arrays x and y are formed such that x has k members from GF(2^{m}) and y has (n−k) members from GF(2^{m}) while ensuring that no member that is in x is also in y. Then the special Cauchy matrix 304 is formed as M(i,j)=1/(xᵢ+yⱼ), where i is the i^{th} row and j is the j^{th} column in the special Cauchy matrix 304, for 1≤i≤(n−k); 1≤j≤k.

As an example, with (n−k)=3 and k=12, array x comprises={0, 1, 2, 3, 4, 5, 6, 7, 8, 9, 10, 11} and array y={12, 13, 14}, where the entries in array x and array y are the powers of α from FIG. 5. Using the properties of matrix addition and multiplication, the special Cauchy matrix 304 is computed using M(3,12)=1/(xᵢ+yⱼ) to be:

$$M = [ \begin{matrix}4 & 2 & 8 & 5 & 9 & 1 & 11 & 13 & 6 & 7 & 12 & 0 \\ 9 & 3 & 1 & 7 & 4 & 8 & 0 & 10 & 12 & 5 & 6 & 11 \\ 12 & 8 & 2 & 0 & 6 & 3 & 7 & 14 & 9 & 11 & 4 & 5\end{matrix} ]$$

An important property of the special Cauchy matrix 304 is that any square-sub-matrix formed by taking any number of arbitrary rows and an equal number of arbitrary columns from those rows is invertible. For example, taking rows 1 and 3 and columns 2 and 3 from those two rows we can form

$${M}_{1323} = [ \begin{matrix}2 & 8 \\ 8 & 2\end{matrix} ] .$$

As another example of a square sub-matrix, take rows 1, 2, 3 and columns 2, 5, 7 from those rows:

$${M}_{123257} = [ \begin{matrix}2 & 9 & 11 \\ 3 & 4 & 0 \\ 8 & 6 & 7\end{matrix} ]$$

Once the special Cauchy matrix 304 has been determined, it is concatenated with identity matrix 302, to yield the encoding matrix shown in FIG. 3.

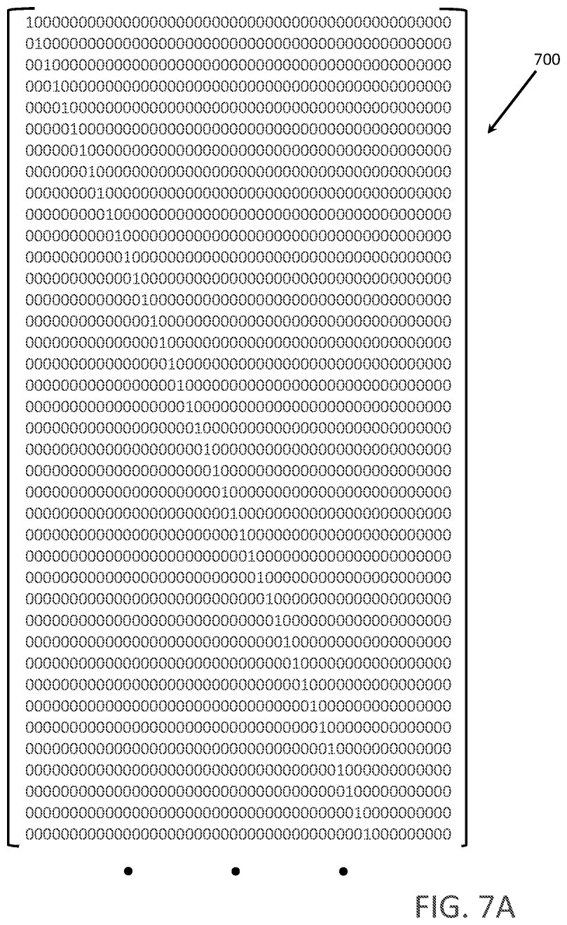

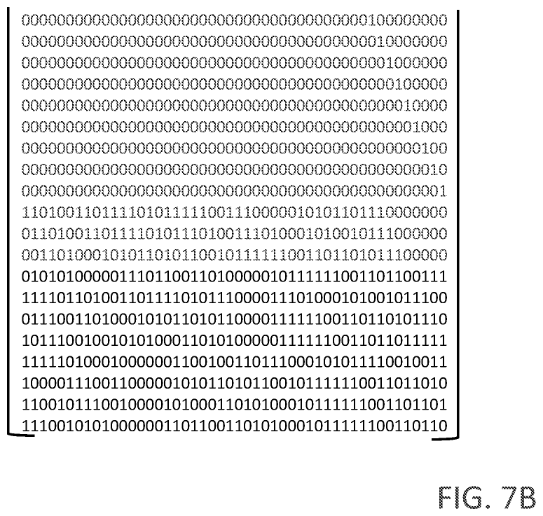

At block 406, a binary encoder matrix 700 is formed from the encoding matrix 300, as shown in FIGS. 7A and 7B. Binary encoder matrix 700 is formed by replacing each element in the encoding matrix 300 by a respective 4×4 binary matrix, the formation of each matrix described below. The result, in this embodiment, is a binary matrix 60 rows by 48 columns. The first 48 rows and 48 columns represent the identity matrix in binary form and the last 12 rows and 48 columns represent the special Cauchy matrix in binary form. Once the binary encoder matrix 700 is formed, it is stored in memory 202.

In the encoding matrix 300, element “−1” is represented by an all-zero matrix of size 4×4. For the remaining elements, referring to FIG. 5, each element can be represented as a 4×4 matrix as follows: take its vector representation [C₁ C₂ C₃ C₄] and make it the first column in the matrix. Then take the next three rows in the extension field table and make them the next three columns of the matrix. In the process of picking the “next three rows”, if there are not enough rows in the extension field, a next row is selected by “wrapping” around back to the second row of the extension field table (i.e., skipping the “all-zero” or first row. For example, the matrix representations M₄, M₁₃, and M₁₁ of α⁴, α¹³, and α¹¹ are given below:

$${M}_{4} = [ \begin{matrix}1 & 0 & 0 & 1 \\ 1 & 1 & 0 & 1 \\ 0 & 1 & 1 & 0 \\ 0 & 0 & 1 & 1\end{matrix} ]$$

$${M}_{13} = [ \begin{matrix}1 & 1 & 1 & 0 \\ 0 & 0 & 0 & 1 \\ 1 & 0 & 0 & 0 \\ 1 & 1 & 0 & 0\end{matrix} ]$$

$${M}_{11} = [ \begin{matrix}0 & 1 & 1 & 1 \\ 1 & 1 & 0 & 0 \\ 1 & 1 & 1 & 0 \\ 1 & 1 & 1 & 1\end{matrix} ]$$

An m-bit vector in GF(2^{m}) is referred to herein by the power of a that corresponds to that vector. For example, the vector [1 1 0 0] in FIG. 5 is denoted by 4, since [1 1 0 0] is denoted by α⁴.

At block 408, input/output data transfer logic receives data from one of the hosts 102 and, in response, generates a 48-bit binary information vector u.

At block 410, encoder 206 generates a systematic, binary codeword v_{bin} by performing matrix multiplication on the binary information vector and binary encoder matrix 700. Matrix multiplication comprises XOR additions, as described above and, thus, complex arithmetic is avoided. The resultant codeword is 60 bits in length, comprising 48 information bits that are identical to the bits in the binary information vector with 12 parity bits appended to the end of the information bits.

In one embodiment, encoder 206 does not multiply the binary information vector by the entire binary encoder matrix 700, because the codeword is systematic. That is, the first 48 bits in the 60 bit binary codeword v_{bin} are same as the information bits in the vector u_{bin}. Thus, only the last 12 bits—i.e., the parity bits—need to be generated and appended to the information bits. In this embodiment, then, encoder 206 multiplies the binary information vector by a binary representation of the special Cauchy matrix 304, i.e., the last 12 rows and all 48 columns of the binary encoder matrix 700, to generate the 12 parity bits.

As an example, the 48-bit binary information vector u may comprise u_{bin}=[0 1 0 1 0 0 1 0 1 1 0 1 1 0 0 0 0 0 1 1 0 1 1 0 1 1 1 1 1 1 1 1 1 1 0 0 1 1 1 1 1 0 0 0 0 0 0 1]. The binary codeword v_{bin} is 60-bits long, where the first 48 bits are the same as u_{bin}. The last 12 bits of v_{bin}—which are the parity bits—are generated by encoder 206 computing the matrix product M_{bin}*u_{bin}, (where M_{bin} is the binary representation of the special Cauchy matrix), resulting in 1 0 1 0 1 0 1 1 1 0 0 1. By appending these 12 parity bits to u_{bin}, the 60-bit codeword v_{bin}=[0 1 0 1 0 0 1 0 1 1 0 1 1 0 0 0 0 0 1 1 0 1 1 0 1 1 1 1 1 1 1 1 1 1 0 0 1 1 1 1 1 0 0 0 0 0 0 1 1 0 1 0 1 0 1 1 1 0 0 1] is formed.

At block 412, the codeword is apportioned into a number of codeword symbols, each symbol 4 bits in length, yielding 12 information symbols and 3 parity symbols.

At block 414, each codeword symbol is stored by encoder 206 in a respective one of the storage mediums 108, in this case there are 15 storage mediums.

At block 416, a request to retrieve data (i.e., one or more codewords) is received by input/output data transfer logic 204.

At block 418, in response to receiving the request to retrieve data, decoder 208 retrieves a respective codeword symbol from each of the storage media 108a-108ₒ. (i.e., 15 storage mediums, the first 12 mediums storing codeword symbols representing the information bits, and the last 3 mediums storing codeword symbols representing the parity bits). However, one or more of the codeword symbols may not be available, due to a malfunction of one or more of the storage media 108, or a communication problem between one or more storage mediums and decoder 208. For purposes of discussion for the remainder of the steps in this method, it will be assumed that 3 storage mediums failed during a retrieval by decoder 208 and, specifically, that storage mediums 108j, 108k and 108l failed, representing the last 12 bits of the binary information vector.

Referring back to the 15×12 encoding matrix G shown in FIG. 5, each column represents an information symbol and each row represents a codeword symbol. Since the codeword is systematic, the first 12 rows of encoding matrix G corresponds to the information symbols of an extension field information vector, and the last three rows of encoding matrix G correspond to the parity symbols. If the 12 columns of the encoding matrix G are labeled {0, 1, . . . , 11} and the rows as {0, 1, . . . , 14}, the failed information symbols represent columns {9, 10, 11} in the encoding matrix G and the parity symbols represent rows {12, 13, 14} in the encoding matrix G.

For ease of discussion, the following blocks 420-426 are described in terms of extension field elements in encoding matrix G, rather than the bits in binary encoder matrix 700. It should be understood that in one embodiment, encoding matrix G is not stored in memory 202 and, therefore, not available to processor 200 or decoder 208 during the calculations described in blocks 420-426. However, binary encoder matrix 700 is stored in memory 202 or some other memory, and so, in practice, processor 200 and/or decoder 208 uses the 4×4 binary matrix representations of the extension field elements to perform the calculations described in blocks 420-426. In another embodiment, the encoding matrix G is also stored in memory 202 or some other memory along with the binary encoder matrix 700, the blocks 420-426 are performed as described below.

At block 420, decoder 208 defines an array xₜ={9, 10, 11} and an array yₜ={12, 13, 14}. The entries in xₜ are identical to the failed symbol numbers and the entries in yₜ identical to the parity symbols because of the way the special Cauchy matrix 304 was formed. If a different set of values in the x and y arrays were chosen, there would not be a straightforward correspondence between xₜ and the failed symbol numbers and yₜ and the parity symbol numbers, and two tables would need to be defined and stored in memory 202, a first table for mapping column numbers to the entries in x to generate xₜ and another table for mapping entries in y to generate yₜ.

At block 422, decoder 208 generates a square sub-matrix from the encoding matrix G that corresponds to the rows denoted in yₜ and the columns denoted in xₜ. In this example, this square sub-matrix shall be referred to as sub-matrix D and, therefore:

$$D = [ \begin{matrix}7 & 12 & 0 \\ 5 & 6 & 11 \\ 11 & 4 & 5\end{matrix} ]$$

Instead of three storage medium failures, if only two failures were encountered when retrieving data from the storage mediums, D would be formed from a respective two columns in the encoding matrix G and any two of the three parity symbols in those two columns. For example, if symbols 10 and 11 failed, any two of the three parity rows in the encoding matrix G by decoder 208, either rows 12 and 13, rows 12 and 14, or rows 13 and 14. For example, if rows 12 and 14 are selected, D is calculated to be:

$$D = [ \begin{matrix}7 & 12 \\ 11 & 4\end{matrix} ]$$

At block 424, decoder 208 generates an inverse of D, referred to herein as a D⁻¹ matrix, as follows. If a is defined as the number of entries in xₜ and yₜ, for k=1:a,

aₖ=Π_{i<k}(xtᵢ−xtₖ)Π_{k<j}(xtₖ−xtⱼ)

bₖ=Π_{i<k}(ytᵢ−ytₖ)Π_{k<j}(ytᵢ−ytₖ)

eₖ=Πᵢ₌₁^{a}xtₖ+ytᵢ

fₖ=Πᵢ₌₁^{a}ytₖ+xtᵢ

Once the above quantities are calculated, the entries in D⁻¹ are computed as follows:

$${d}_{ij} = {( - 1 )}^{i + j} \frac{{e}_{j} {f}_{i}}{{a}_{j} {b}_{i} ( {xt}_{j} + {yt}_{i} )}$$

for dᵢⱼ, 1≤i≤α; 1≤j≤α. After performing the above calculations, in this example, D⁻¹ is equal to:

$${D}^{- 1} = [ \begin{matrix}4 & 2 & 6 \\ 13 & 7 & 3 \\ 3 & 14 & 6\end{matrix} ]$$

In one embodiment, rather than compute the D⁻¹ matrix as described in blocks 420-424, a plurality of D⁻¹ matrices could be stored in memory 202 or some other storage device, each D⁻¹ matrix associated with a particular combination of disks or codeword symbols that failed. In the present example, with 12 information symbols/disks and a tolerance of up to 3 disk failures, the number of unique D⁻¹ matrices that would need to be stored in memory 202 would be 220. Then, processor 200 would select a particular D⁻¹ matrix from the plurality of D⁻¹ matrices depending on which combination of disks/symbols failed. Each of the plurality of D⁻¹ matrices could be stored in either extension field form or binary form. If stored in extension field form, processor 200 converts a selected D⁻¹ matrix to binary form for use in the last step of block 426, described below.

At block 426, decoder 208 generates the failed information symbols as follows.

First, decoder 208 stores a representation of the codeword symbols/storage mediums that did not fail in an array I, and stores a representation of the parity rows selected at block 424 in an array J. The two arrays are generally stored in memory 202. Referring to the above example, I={0, 1, 2, 3, 4, 5, 6, 7, 8} and J={12, 13, 14}.

Next, decoder 208 selects an entry j from J, and selects that row number in the encoding matrix G. Then, for each entry i in I, decoder 208 selects an element from G(j,i) and computes its matrix representation, as described previously herein. In practice, each element (G(j,i) is already in 4×4 binary matrix form, as only binary encoder matrix 700 is typically stored in memory 202 or some other memory. Next, decoder 208 multiplies that matrix with a vector representation of symbol i. The will result in a 4×1 vector. This operation is performed for all i in I.

After performing this operation for all i in I, an III number of 4×1 vectors will have been generated, where III denotes the number of elements in I, in this case 9. Each of the 4×1 vectors may be stored in memory 202.

Next, decoder 208 performs a bit-by-bit XOR addition of all of the 4×1 vectors. The result is a 4×1 vector, which is then XOR-added with the bit vector representation of the jth parity symbol in the codeword, which can be obtained from the binary codeword v_{bin} stored in memory 202. The result is a 4×1 vector which will be referred to as bⱼ.

The above procedure for repeated for each element in J., resulting in a |J| number of 4×1 column vectors b₃, where |J| denotes the number of elements in J, or the number of failed storage mediums, in this case 3.

Next, decoder 208 concatenates, or stacks, the resulting bⱼ vectors, one below another. In the current example, this will generate a 12×1 bit column vector, referred to herein as E.

Next, decoder 208 replaces each member in D⁻¹ by its corresponding 4×4 bit matrix, as explained previously. In practice, each member in D⁻¹ is already in 4×4 binary matrix form, as only binary encoder matrix 700 is typically stored in memory 202 or some other memory. Therefore, this step may not actually be performed by processor 200. In the current example, decoder 208 generates a 12×12 bit matrix, referred to herein as Dinv_{bin}.

Finally, the failed codeword symbols are generated as the product of Dinv_{bin} and E (i.e., R=Dinv_{bin}*E) in bit vector form, stacked one below another in a column. In the current example, R is a 12×1 bit column vector where the first 4 bits is the recovered 9^{th} codeword symbol, the next 4 bits is the recovered 10^{th} codeword symbol, and the last 4 bit-vector is the recovered 11^{th} codeword symbol.

At block 428, decoder 208 arranges the codeword symbols that were retrieved successfully with the recovered codeword symbols to form the original codeword. The parity bits may be stripped, and the information bits of the codeword are provided to input/output data transfer logic, where the information is provided to a host 102 that requested the information.

In some data center applications, a disk-duplication scheme is used to provide redundancy in the event of disk failure. For example, a source disk may be replicated onto 3 other disks, and such a system can tolerate up to three, simultaneous disk failures. However, this approach is costly in terms of storage, because the overhead is 75%. (overhead may be defined as the number of additional disks divided by the total number of disks, in this case, ¾). The system described herein, on the other hand, comprises an overhead of (n−k)/n, which is typically much less than traditional systems. For example, when m=4, n=15. If it is desired to tolerate up to 3 disk failures, 3 parity disks are used. Therefore, in such a system, the overhead is 3/15=20%. If 4 parity disks are allocated, up to 4 disk failures may be tolerated, and such a system comprises an overhead of only 4/15=26.66% vs. an overhead of 4/5=80% for a traditional replication system.

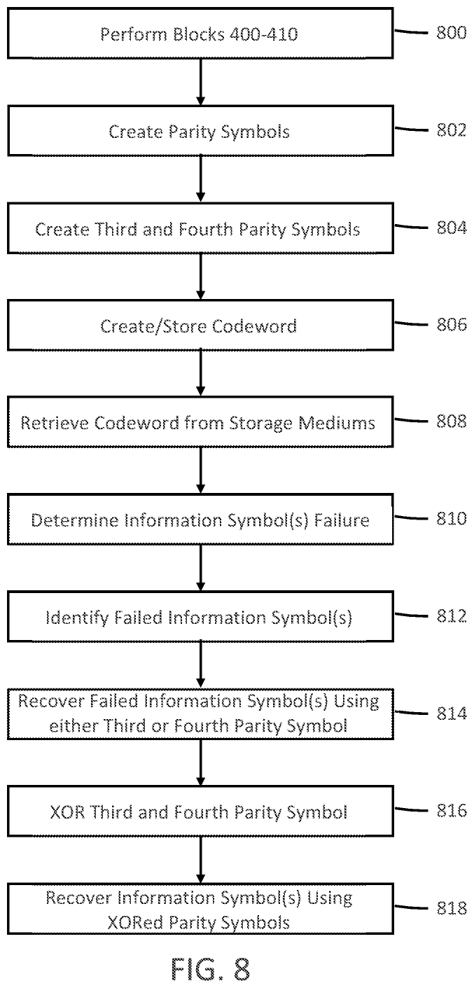

FIG. 8 is a flow diagram illustrating an alternative embodiment of a method performed by data storage server 104 to encode, store, retrieve and decode data received from one or more hosts 102. In this embodiment, the method is described as being performed by input/output data transfer logic 204, encoder 206, decoder 208 and processor 200, executing processor-executable instructions stored in memory 202 or in a memory associated with one of the aforementioned processing devices. It should be understood that the steps shown in FIG. 8 could alternatively be performed by processor 200 controlling functions provided by input/output data transfer logic 204, encoder 206, and decoder 208. It should be further understood that in some embodiments, not all of the steps shown in FIG. 8 are performed and that the order in which the steps are carried out may be different in other embodiments. It should be further understood that some minor method steps have been omitted for purposes of clarity.

The number of disks needed to reconstruct a failed disk may be referred to as the repair bandwidth. In the method described in FIGS. 4A and 4B, the repair bandwidth is k, with k=12 and n=15. Continuing with the example described in FIGS. 4A and 4B, to recover one failed storage medium, decoder 208 must read data from twelve disks: eleven information disks and one parity disk. Generally, it is desirable to reduce the repair bandwidth for the most-frequent failure scenario, which is failure of one disk, while being capable of recovery of more-than-one disk failure. The method described below reduces the repair bandwidth by a factor of 2 in the case of single disk failure, while enabling recovery of more than 1 disk failure, in this example up to 3 failed disks.

At block 800, blocks 400-410 of the method described above are performed, i.e., defining system parameters, defining an encoding matrix comprising an identity matrix concatenated with a special Cauchy matrix, converting the encoding matrix into a binary encoder matrix, receiving data from one or more hosts, and generating a binary information vector v_{bin} 48 bits in length. However, a fourth parity disk 108n+1 (as shown in FIG. 1) is added, such that data storage and retrieval system 100 now comprises 16 storage mediums, 12 used to store information symbols and 4 used to store parity symbols. So, q=2^{m}, m=4, and so n=(q)=16, k=12 and 4 parity symbols.

At block 802, encoder 206 creates two parity symbols, as described above at block 414, by multiplying the binary information vector with rows 49-56 of the binary encoder matrix 700. However, rather than creating the third parity symbol by multiplying the binary information vector with rows 57-60, encoder 206 creates a third parity symbol from the last four rows of binary encoder matrix 700 and a fourth parity symbol, also using the last four rows of binary encoder matrix 700. The third and fourth parity symbols are created by processor 200 as follows.

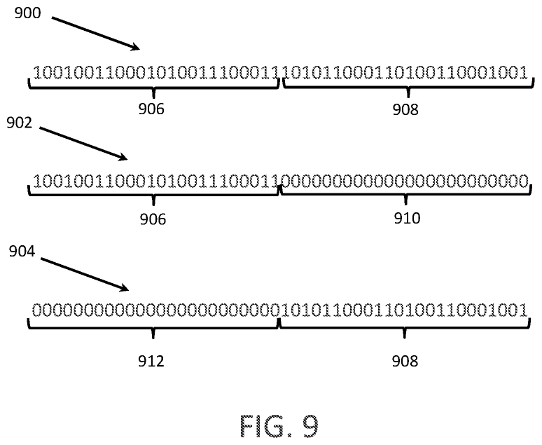

As shown in FIG. 9, processor 200 generates a first binary vector 902 and a second binary vector 904, each from the 48 bit binary information vector v_{bin} 900. The first binary vector 802 is the same length as the binary information vector v_{bin} 900, comprising the first half 906 of the bits of the binary information vector v_{bin} 900 (i.e., 24 bits in this case), followed by all zeros 910. The second binary vector 904 is also the same length as the binary information vector V_{bin} 900, comprising all zeros 912 followed by the second half 908 of the bits of the binary information vector v_{bin} 900. It should be understood that in another embodiment, first binary vector 902 and second binary vector 904 could have been created from an information vector in an extension field domain, and then the resultant extension field first and second vectors converted into binary form. It should also be understood that although the first and second vectors 902 and 904 each comprise one-half of the information bits in the binary information vector v_{bin} 900, in other embodiments, each of the vectors 902 and 904 could contain a different number of bits from the binary information vector v_{bin} 900. For example, first vector 902 is the same length as the binary information vector v_{bin} 900, however comprising the first 16 bits of the binary information vector v_{bin} 900, followed by 32 zeros, while the second binary vector 904 comprises 16 zeros followed by the last 32 bits of the binary information vector v_{bin} 900. Finally, if the number of symbols in the binary information vector v_{bin} 900 is odd, vector 902 is formed from the first half of symbols of the binary information vector v_{bin} 900, and vector 404 is formed from the remaining symbols of the binary information vector v_{bin} 900.

At block 804, encoder 206 multiplies the first vector 902 by last four rows of the binary encoder matrix 700 to form the third parity symbol, and the second vector 904 is multiplied by the last four rows of the binary encoder matrix 700 to form the fourth parity symbol. It should be understood that although, in this example, the third and fourth parity symbols were created from the last four rows of the binary encoder matrix 700, in other embodiments, any group of four parity rows of the binary encoder matrix 700 could be used.

At block 806, a systematic codeword is formed from the 48 information bits of the binary information vector v_{bin} 900, concatenated with first and second parity symbols, generated as described by the method of FIGS. 4A and 4B, followed by the third and fourth parity symbols. As before, the systematic codeword is then apportioned into information symbols and parity symbols, and each symbol is stored on a respective storage medium 108, with the third parity symbol stored in storage medium 108n, and the forth parity symbol stored in a storage medium 108ₙ₊₁.

At block 808, at some time later, the systemic codeword is retrieved from the storage mediums 108 by decoder 208.

At block 810, decoder 208 determines if any symbols of the codeword were erased, i.e., not provided by one or more of the storage mediums 108 due to, for example, a hardware failure of one of the storage mediums or a disconnect between a storage medium and decoder 208.

At block 812, if a single symbol was erased or otherwise unavailable, decoder 208 determines which codeword symbol failed out of the 12 information symbols of the codeword. For example, decoder 208 may determine that information symbol 3 failed, corresponding to storage medium 108_{c}.

At block 814, decoder 208 recovers the failed information symbol as described in block 428 above, using the third parity symbol from storage medium 108, if the failed information symbol is from storage mediums 108ₐ-108_{f}, or using the fourth parity symbol from storage medium 108ₙ₊₁ if the failed information symbol is from storage mediums 108_{g}-108ₗ. However, the array I comprises representations of only intact information symbols in either the first-half or the second-half of the set of storage mediums to which the failed information symbol belongs. Referring to the current example, if the failed information symbol was information symbol 3 that had been stored in storage medium 108_{c}, array I comprises {1, 2, 4, 5, 6}. If the failed information symbol was the 10^{th} information symbol of the codeword, array I would comprise {7, 8, 9, 11, 12}.

In other embodiments, a different “mapping” of failed-symbol-to-parity-symbol scheme may be defined, such as using the third parity symbol when odd information symbols fail, and using the fourth parity symbol when even information symbols fail. In these alternative embodiments, each of the third and fourth parity symbols are derived in accordance with the alternative mapping scheme. Continuing with the odd/even scheme just described, the third parity symbol is generated from even groupings of 4 bits each of the binary information vector v_{bin} 900 (i.e., bits {5, 6, 7, 8}, {13, 14, 15, 16}, {21, 22, 23, 24}, etc.), inserting 4 zeros in between each of the even groupings, while the fourth parity symbol is generated from odd groupings of 4 bits each of the binary information vector v_{bin} 900 (i.e., bits {1, 2, 3, 4}, {9, 10, 11, 12}, {17, 18, 19, 20}, etc.), also inserting 4 zeros in between each of the odd groupings.

At block 816, if more than one storage medium fails, decoder 208 XORs the third and fourth parity symbols together, creating an original parity symbol, i.e., a parity symbol that would have been created by multiplication of the binary information vector v_{bin} 900 with the last four rows of the binary encoder matrix 700, as described in FIGS. 4A and 4B.

At block 818, the failed codeword symbols are re-created, using the decoding method of FIGS. 4A and 4B, beginning at block 428.

This modification to the method of FIGS. 4A and 4B reduces the repair bandwidth by a factor of 2 for the case of a single storage medium failure while retaining the ability to recover from multiple storage medium failures.

The methods or algorithms described in connection with the embodiments disclosed herein may be embodied directly in hardware or embodied in processor-readable instructions executed by a processor. The processor-readable instructions may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components.

Accordingly, an embodiment of the invention may comprise a computer-readable media embodying code or processor-readable instructions to implement the teachings, methods, processes, algorithms, steps and/or functions disclosed herein.

It is to be understood that the decoding apparatus and methods described herein may also be used in other communication situations and are not limited to RAID storage. For example, compact disk technology also uses erasure and error-correcting codes to handle the problem of scratched disks and would benefit from the use of the techniques described herein. As another example, satellite systems may use erasure codes in order to trade off power requirements for transmission, purposefully allowing for more errors by reducing power and chain reaction coding would be useful in that application. Also, erasure codes may be used in wired and wireless communication networks, such as mobile telephone/data networks, local-area networks, or the Internet. Embodiments of the current invention may, therefore, prove useful in other applications such as the above examples, where codes are used to handle the problems of potentially lossy or erroneous data.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A distributed data encoding and storage method that provides for XOR-only decoding, comprising:
generating an information vector from received data, the information vector comprising information symbols;
generating a codeword from the information vector, the codeword comprising the information symbols and parity symbols; and
distributing the information symbols and the parity symbols to a plurality of storage mediums, respectively;
wherein the parity symbols are formed by multiplying the information vector by a portion of a binary encoder matrix, the portion of the binary encoder matrix comprising a binary representation of a Cauchy matrix.

2. The distributed data encoding and storage method of claim 1, wherein the Cauchy matrix comprises a plurality of sub-matrices, each of the plurality of sub-matrices comprising a matrix representation of a respective power of a primitive of a first polynomial.

3. The distributed data encoding and storage method of claim 2, wherein each of the respective powers of a primitive is associated with a respective combination of coefficients of a second polynomial.

4. The distributed data encoding and storage method of claim 3, wherein the matrix representation of a first power of the primitive comprises a first column of elements formed from a first row of coefficients in an encoding matrix, and a second column of elements formed from a second row of coefficients of the encoding matrix.

5. The method of claim 3, wherein the matrix representation of a last power of the primitive comprises a first column of elements formed from a last row of coefficients in the encoding matrix, and a second column formed from a first non-zero row of coefficients of the encoding matrix.

6. The distributed data encoding and storage method of claim 1, wherein generating the codeword comprises:
appending the parity symbols to the information symbols.

7. The distributed data encoding and storage method of claim 1, wherein the binary encoder matrix comprises a binary representation of an encoding matrix, the encoding matrix comprising an identity matrix concatenated with the Cauchy matrix, wherein each element of the encoding matrix is an element of an extension field.

8. The distributed data encoding and storage method of claim 1, further comprising:
retrieving the plurality of symbols from the plurality of storage mediums;
identifying at least one failed symbol of the retrieved plurality of symbols; and
re-creating the information vector using only XOR arithmetic on the symbols that were successfully retrieved.

9. The distributed data encoding and storage method of claim 8, wherein recovering the information vector using only XOR arithmetic comprises:
identifying a sub-matrix within the Cauchy matrix in accordance with an identity of the failed symbols;
computing an inverse matrix from the sub-matrix;
generating a column vector from codeword symbols that did not fail; and
multiplying the inverse matrix by the column vector.

10. The distributed data encoding and storage method of claim 9, wherein generating a column vector from codeword symbols that did not fail comprises:
a) storing representations i of the information symbols that did not fail in a first array I;
b) storing representations j of one or more parity rows of the Cauchy matrix in a second array J;
for each representation j in J:
for each representation i in I:
c) identifying a binary matrix from the binary encoder matrix in accordance with j and i;
d) multiplying the binary matrix by a vector representation of a respective information symbol i that did not fail;
e) storing a result of step d in a memory;
f) repeating steps c-d for each representation i, generating a plurality of results;
g) performing XOR addition each on the plurality of results to generate a first vector;
h) performing XOR addition on the first vector and a vector representation of a parity symbol associated with j, resulting in a second vector;
i) repeating steps c-h for each representation j, generating a plurality of second vectors; and
j) concatenating each of the plurality of second vectors to form the column vector.

11. The distributed data encoding and storage method of claim 1, further comprising:
generating a first parity symbol based on a first subset of information in the binary information vector;
generating a second parity symbol based on a remaining subset second half of information in the binary information vector;
determining that a first information symbol of the codeword failed;
recovering the first information symbol using the first parity symbol when the first information symbol was stored in a first storage medium belonging to a first set of the plurality of storage mediums; and
recovering the first information symbol using the second parity symbol when the first information symbol was stored in a second storage medium belonging to a second set of the plurality of storage mediums.

12. A method for data recovery in a distributed data storage system, comprising:
retrieving a plurality of information symbols and a plurality of parity symbols from a plurality of storage mediums, the plurality of information symbols and plurality of parity symbols comprising a codeword formed from a binary information vector and a binary encoder matrix, wherein the binary encoder matrix comprises a binary representation of an identity matrix concatenated with a Cauchy matrix;
determining that at least one of the information symbols failed;
identifying a sub-matrix within a portion of the binary encoder matrix representative of the Cauchy matrix, the sub-matrix identified in accordance with an identity of the failed information symbols;
computing an inverse matrix from the sub-matrix;
generating a column vector from information symbols that did not fail; and
multiplying the inverse matrix by the column vector.

13. The method of claim 12, wherein the sub-matrix comprises a square matrix comprising a number of rows and columns equal to a number of failed information symbols.

14. The method of claim 12, wherein the Cauchy matrix comprises binary matrix representations of powers of a primitive in an extension field.

15. The method of claim 12, wherein generating a column vector from codeword symbols that did not fail comprises:
a) storing representations i of the information symbols that did not fail in a first array I;
b) storing representations j of one or more parity rows of the Cauchy matrix in a second array J;
for each representation j in J:
for each representation i in I:
c) identifying a binary matrix from the binary encoder matrix in accordance with j and i;
d) multiplying the binary matrix by a respective vector representation of an information symbol i that did not fail;
e) storing a result of step d in a memory;
f) repeating steps c-d for each representation i, generating a plurality of results;
g) performing XOR addition each on the plurality of results to generate a first vector;
h) performing XOR addition on the first vector and a parity symbol associated with j, resulting in a second vector;
i) repeating steps c-h for each representation j, generating a plurality of second vectors; and
j) concatenating each of the plurality of second vectors to form the column vector.

16. The method of claim 12, further comprising:
generating a first parity symbol based on a first subset of information in the binary information vector;
generating a second parity symbol based on a remaining subset second half of information in the binary information vector;
storing the first parity symbol in a first storage medium;
storing the second parity symbol in a second storage medium;
determining that a first information symbol of the codeword failed;
recovering the first information symbol using the first parity symbol when the first information symbol was stored in a third storage medium belonging to a first set of the plurality of storage mediums; and
recovering the first information symbol using the second parity symbol when the first information symbol was stored in a fourth storage medium belonging to a second set of the plurality of storage mediums.

17. A non-transient computer-readable medium for storing processor-executable instructions that cause a distributed data storage and retrieval system to:
retrieve a plurality of information symbols and a plurality of parity symbols from a plurality of storage mediums, the plurality of information symbols and plurality of parity symbols comprising a codeword formed from a binary information vector and a binary encoder matrix, wherein the binary encoder matrix comprises a binary representation of an identity matrix concatenated with a Cauchy matrix;
determine that at least one of the information symbols failed;
identify a sub-matrix within a portion of the binary encoder matrix representative of the Cauchy matrix, the sub-matrix identified in accordance with an identity of the failed information symbols;
compute an inverse matrix from the sub-matrix;
generate a column vector from information symbols that did not fail; and
multiply the inverse matrix by the column vector.

18. The computer-readable medium of claim 17, wherein the sub-matrix comprises a square matrix comprising a number of rows and columns equal to a number of bits in the information symbols.

19. The computer-readable medium of claim 17, wherein the Cauchy matrix comprises binary matrix representations of powers of a primitive polynomial in an extension field.

20. The computer-readable medium of claim 17, wherein the instructions that causes the data storage and retrieval system to generate a column vector from codeword symbols that did not fail comprises instructions that causes data storage and retrieval system to:
a) store representations i of the codeword symbols that did not fail in a first array I;
b) store representations j of two or more parity rows of the Cauchy matrix in a second array J;
for each representation j in J:
for each representation i in I:
c) identifying a binary matrix from the binary encoder matrix in accordance with j and i;
d) multiplying the binary matrix by a respective vector representation of an information symbol i that did not fail;
e) storing a result of step d in a memory;
f) repeating steps c-d for each representation i, generating a plurality of results;
g) performing XOR addition each on the plurality of results to generate a first vector;
h) performing XOR addition on the first vector and a parity symbol associated with j, resulting in a second vector;
i) repeating steps c-h for each representation j, generating a plurality of second vectors; and
j) concatenating each of the plurality of second vectors to form the column vector.

21. The computer-readable medium of claim 17, further comprising instructions that causes the data storage and retrieval system to:
generate a first parity symbol based on a first subset of information in the binary information vector;
generate a second parity symbol based on a remaining subset second half of information in the binary information vector;
store the first parity symbol in a first storage medium;
store the second parity symbol in a second storage medium;
determine that a first information symbol of the codeword failed;
recover the first information symbol using the first parity symbol when the first information symbol was stored in a third storage medium belonging to a first set of the plurality of storage mediums; and
recover the first information symbol using the second parity symbol when the first information symbol was stored in a fourth storage medium belonging to a second set of the plurality of storage mediums.
